(19) United States
(12) Patent Application Publication
(10) Pub. No.: US 2006/0141699 A1
(43) Pub. Date: Jun. 29, 2006

(54) Method for fabricating semiconductor memory device

(75) Inventor: Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/320,204

(22) Filed: Dec. 28, 2005

(30) Foreign Application Priority Data
Dec. 28, 2004 (KR) 2004-0114013

(51) Int. Cl. H01L 21/8242; H01L 21/20

(52) U.S. Cl. 438/243; 438/386

(57) ABSTRACT

A method for fabricating a semiconductor memory device is provided. The method includes: forming an inter-layer insulation layer with a storage node contact hole on a substrate; forming storage node contact spacers on sidewalls of the inter-layer insulation layer in the storage node contact hole; forming a storage node contact plug in the storage node contact hole; recessing the inter-layer insulation layer in a predetermined depth; forming an etch stop insulation layer and an insulation layer over the resulting structure obtained from the recessing of the inter-layer insulation layer; sequentially dry etching the insulation layer and the etch stop insulation layer to form an opening, exposing a portion of the storage node contact spacers and the storage node contact plug; forming a bottom electrode in the opening; and sequentially forming a dielectric layer and an upper electrode on the bottom electrode.

### FIELD OF THE INVENTION

The present invention relates to a method for fabricating a semiconductor device.

### DESCRIPTION OF RELATED ARTS

As the minimum line width has decreased and the scale of integration has increased in semiconductor memory devices, the surface area for a capacitor has become smaller. Although the surface area for the capacitor has become smaller, the capacitor in a cell is generally required to secure a high capacitance which is the minimum level demanded in each cell. To form such capacitor with the high capacitance on the small surface area, various methods has been introduced: using materials with a high dielectric constant for a dielectric layer, i.e., tantalum oxide (Ta₂O₅), aluminum oxide (Al₂O₃) and hafnium oxide (HfO₂), instead of a silicon oxide layer (ε=3.8) and a nitride layer (ε=7); forming a bottom electrode three-dimensionally in cylinder-type or in concave-type to effectively increase a surface area of the bottom electrode; growing meta-stable-polysilicon (MPS) on a surface of a bottom electrode to increase an effective area of the bottom electrode by approximately 1.7 to approximately 2 times; and forming a bottom electrode and an upper electrode both by employing a metal layer, i.e., metal-insulator-metal (MIM).

In a dynamic random access memory (DRAM) with a scale of integration equal to or greater than 128 M, a method for fabricating a semiconductor memory device containing a capacitor with a typical MIM concave titanium nitride (TiN) bottom electrode is as follows.

FIGS. 1A and 1B are cross-sectional views illustrating a conventional method for fabricating a semiconductor memory device.

As shown in FIG. 1A, an inter-layer insulation layer 12 is formed on a substrate 11, and then a portion of the inter-layer insulation layer 12 is etched to form a storage node contact hole (not shown) exposing a portion of the substrate 11.

Subsequently, storage node contact spacers 13 are formed on sidewalls of the inter-layer insulation layer 12 in the storage node contact hole. Then, a storage node contact plug 14 is buried in the storage node contact hole. Herein, the storage node contact spacers 13 are formed by employing a silicon nitride layer, and the storage node contact plug 14 is formed by employing polysilicon.

Furthermore, an etch stop insulation layer 15 is formed on the inter-layer insulation layer 12, the storage node contact plug 14, and the storage node contact spacers 13. Then, an insulation layer 16 for use in a storage node is formed on the etch stop insulation layer 15. Herein, the etch stop insulation layer 15 is formed by employing a silicon nitride layer, and the insulation layer 16 is formed by employing a silicon oxide-based oxide layer.

Moreover, a dry etching process is sequentially performed on the insulation layer 16 and the etch stop insulation layer 15 to form an opening 17 exposing a top portion of the storage node contact plug 14.

As shown in FIG. 1B, before forming a TiN bottom electrode, it is essentially required to form a barrier metal for forming the subsequent TiN bottom electrode. Thus, titanium (Ti) is deposited on the above resulting substrate structure by a physical vapor deposition (PVD) method or a chemical vapor deposition (CVD) method, and then, an annealing process is performed to form the barrier metal, titanium silicon (TiSiₓ) 18. Then, non-reacted titanium is removed by a wet etching process.

By forming the barrier metal TiSiₓ 18, resistance on a contacting surface between the storage node contact plug 14 and the subsequent TiN bottom electrode is decreased.

After forming the barrier metal TiSiₓ 18, a TiN layer is deposited over the above resulting substrate structure. Then, portions of the TiN layer on top of the insulation layer 16 are selectively removed to form the TiN bottom electrode 19 contacting the storage node contact plug 14 in the opening 17.

Next, a dielectric layer 20 and a TiN upper electrode 21 are sequentially formed on the TiN bottom electrode 19 to form a capacitor.

However, in the process of etching the etch stop insulation layer 15 formed with silicon nitride while forming the opening 17 in the conventional technology, an overlay occurs between the storage node contact plug 14 and the TiN bottom electrode 19, causing the storage node contact spacers 13 to be over-etched, and as a result, a storage node contact spacer damage is generated. Herein, the storage node contact spacers 13 are over-etched because the storage node contact spacers 13 are formed by employing a silicon nitride layer identical to that of the etch stop insulation layer 15. Due to the storage node contact spacer damage, a portion of the storage node contact spacers 13 is additionally over-etched in a small area next to the storage node contact plug 14, and thus, a crevasse 22 (FIG. 1A) is generated in a thickness ranging from approximately 1,000 Å to approximately 1,500 Å.

The TiN bottom electrode 19, the dielectric layer 20, and the TiN upper electrode 21 are formed by depositing and etching TiN over the above resulting substrate structure with the crevasse 22. Herein, TiN has approximately 50% step coverage. At this time, a space for depositing TiN for use in the TiN upper electrode 21 is either blocked or very narrow. Thus, the TiN upper electrode 21 cannot be formed smoothly, and a projection 24 is generated at the dielectric layer 20 and the TiN upper electrode 21.

Also, due to the above limitation, a structural limitation of the capacitor is occurred, functioning as a leakage current source, and as a result a capacitor leakage current characteristic is deteriorated.

### SUMMARY OF THE INVENTION

It is, therefore, an object of the present invention to provide a method for fabricating a semiconductor memory device capable of removing a capacitor leakage current source generated by a crevasse, wherein the crevasse is formed by a storage node contact spacer damage during an etching process of an etch stop insulation layer.

In accordance with an aspect of the present invention, there is provided a method for fabricating a semiconductor memory device, including: forming an inter-layer insulation layer with a storage node contact hole on a substrate; forming storage node contact spacers on sidewalls of the inter-layer insulation layer in the storage node contact hole; forming a storage node contact plug in the storage node contact hole; recessing the inter-layer insulation layer in a predetermined depth; forming an etch stop insulation layer and an insulation layer over the resulting structure obtained from the recessing of the inter-layer insulation layer; sequentially dry etching the insulation layer and the etch stop insulation layer to form an opening, exposing a portion of the storage node contact spacers and the storage node contact plug; forming a bottom electrode in the opening; and sequentially forming a dielectric layer and an upper electrode on the bottom electrode.

In accordance with another aspect of the present invention, there is provided a method for fabricating a semiconductor memory device, including: forming an oxide-based inter-layer insulation layer with a storage node contact hole on a substrate; forming nitride-based storage node contact spacers on sidewalls of the inter-layer insulation layer in the storage node contact hole; forming a polysilicon-based storage node contact plug in the storage node contact hole; recessing the inter-layer insulation layer in a predetermined depth; forming a nitride-based etch stop insulation layer and an oxide-based insulation layer over the resulting structure obtained from the recessing of the inter-layer insulation layer; sequentially dry etching the insulation layer and the etch stop insulation layer to form an opening, exposing a portion of the storage node contact plug and the storage node contact spacers; forming a bottom electrode in the opening; and sequentially forming a dielectric layer and an upper electrode on the bottom electrode.

### BRIEF DESCRIPTION OF THE DRAWINGS

The above and other objects and features of the present invention will become better understood with respect to the following description of the specific embodiments given in conjunction with the accompanying drawings, in which:

FIGS. 1A and 1B are cross-sectional views illustrating a conventional method for fabricating a semiconductor device; and

FIGS. 2A to 2E are cross-sectional views illustrating a method for fabricating a semiconductor memory device in accordance with a specific embodiment of the present invention.

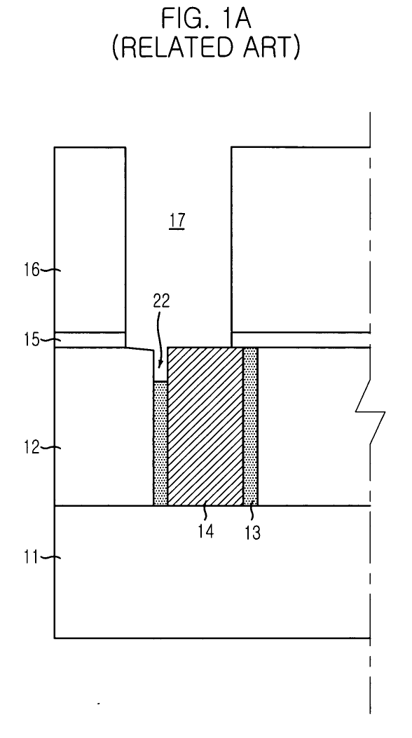

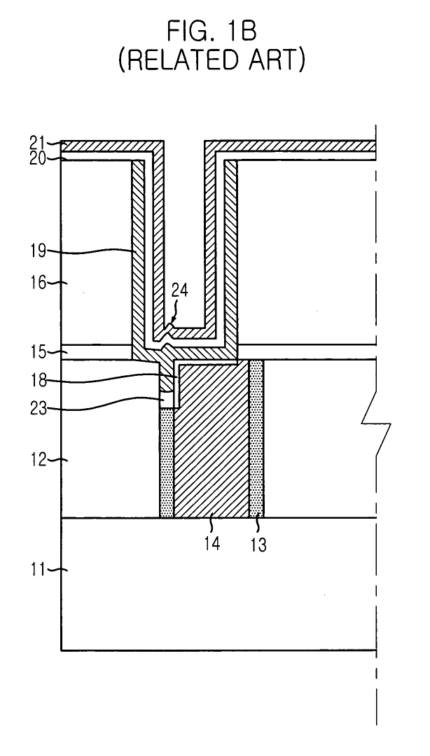

### DETAILED DESCRIPTION OF THE INVENTION

A method for fabricating a semiconductor memory device in accordance with specific embodiments of the present invention will be described in detail with reference to the accompanying drawings.

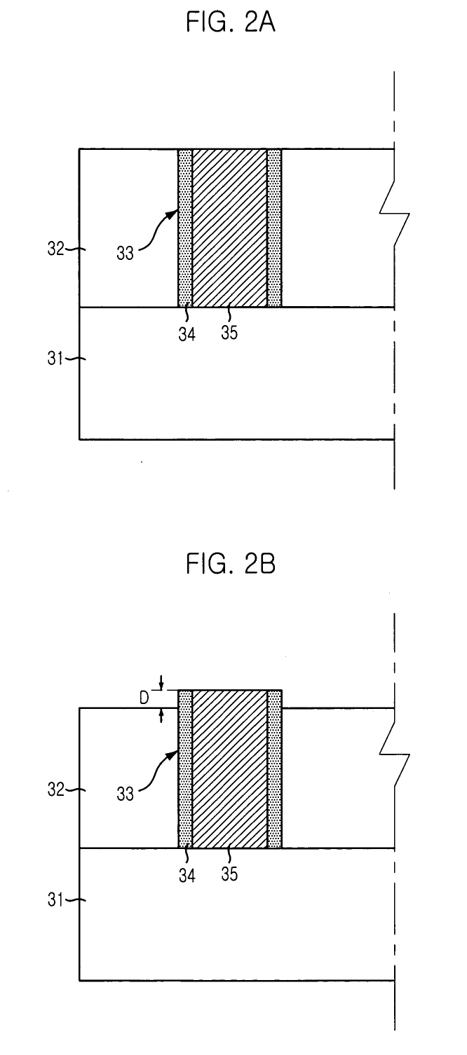

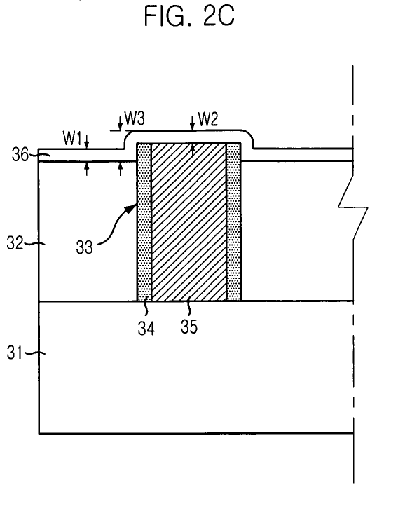

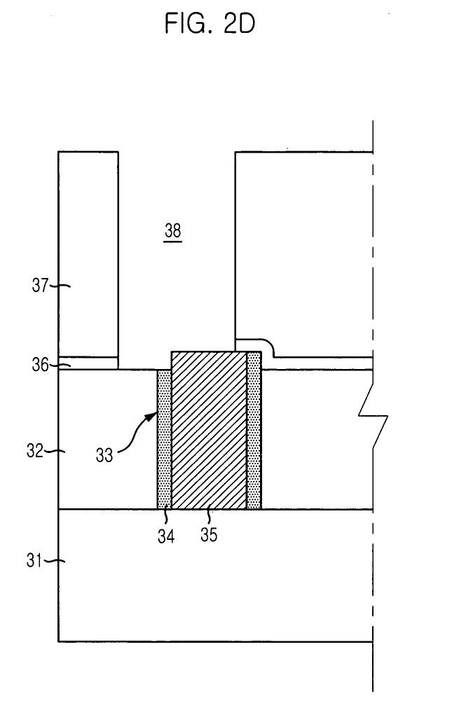

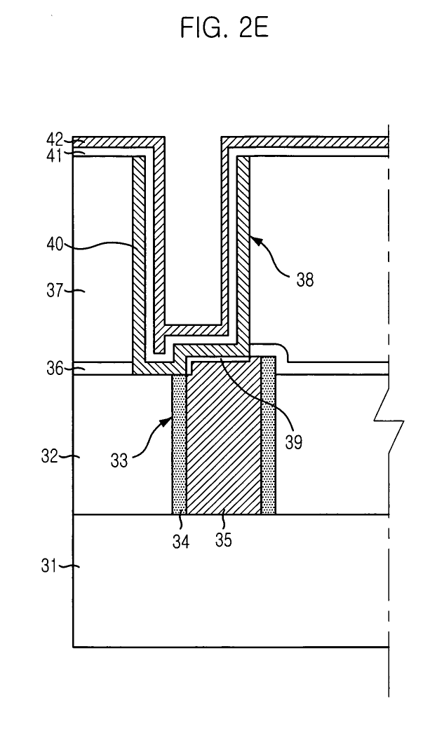

FIGS. 2A to 2E are cross-sectional views illustrating a method for fabricating a semiconductor memory device in accordance with a specific embodiment of the present invention.

As shown in FIG. 2A, an inter-layer insulation layer 32 is formed on a substrate 31. Herein, although not shown, various elements, such as a transistor and a bit line, are formed before the inter-layer insulation layer 32 is formed, as typically known. Thus, the inter-layer insulation layer 32 may be formed with a multiple-layer structure.

Subsequently, a contact mask (not shown) is formed on the inter-layer insulation layer 32 using a photoresist layer. Then, a portion of the inter-layer insulation layer 32 is etched using the contact mask as an etch barrier to form a storage node contact hole 33, exposing a portion of the substrate 31. Herein, the exposed portion of the substrate 31 may become a source/drain junction region.

Furthermore, storage node contact spacers 34 are formed on sidewalls of the inter-layer insulation layer 32 in the storage node contact hole 33. Herein, the storage node contact spacers 34 are formed by forming a silicon nitride (Si₃N₄) layer over the resulting substrate structure, and performing an etch-back process to form sidewall structures, exposing a portion of the substrate 31.

Moreover, a storage node contact plug 35 is buried in the storage node contact hole 33 where the storage node contact spacers 34 are already formed.

Herein, the storage node contact plug 35 is formed by: forming a polysilicon layer over the resulting substrate structure, filling the storage node contact hole 33 where the storage node contact spacers 34 are formed; polishing portions of the polysilicon layer by employing a touch chemical mechanical polishing (TCMP) process; and performing a dry etch process over the resulting substrate structure.

As shown in FIG. 2B, a recess process is performed to recess the inter-layer insulation layer 32 in a predetermined depth, adjacent to the storage node contact plug 35 and the storage node contact spacers 34.

Herein, the recess process includes a dry etch process and a wet etch process. By employing the dry etch process or the wet etch process, the inter-layer insulation layer 32 can be etched faster than the storage node contact plug 35 and the storage node contact spacers 34.

The dry etch process for recessing the inter-layer insulation layer 32 is performed in a radio frequency (RF) plasma chamber, using a fluorine-based gas as a base to adjust an etch rate. That is, if the fluorine-based gas is used to dry etch the inter-layer insulation layer 32, the etch rate of an oxide layer used as the inter-layer insulation layer 32 can be maintained at 2 to 4 times faster than the etch rates of the polysilicon layer used as the storage node contact plug 35 and the silicon nitride layer used as the storage node contact spacers 34, such that the inter-layer insulation layer 32 is selectively recessed. Preferably, the fluorine-based gase includes one of hexafluoroethane (C₂F₆) and carbon tetrafluoride (CF₄).

Also, the wet etch process for recessing the inter-layer insulation layer 32 is performed by employing a hydrogen fluoride (HF) solution or a buffered oxide etchant (BOE) solution. The HF solution and the BOE solution are known for etching an oxide layer faster than a polysilicon layer. Therefore, when recessing the inter-layer insulation layer using the HF solution or the BOE solution, the inter-layer insulation layer 32 can be selectively wet etched without etching the storage node contact plug 35 formed with polysilicon and the storage node contact spacers 34 formed with silicon nitride.

If the dry etch process or the wet etch process is used to recess the inter-layer insulation layer 32, a recess depth ‘D’ ranges from approximately 500 Å to approximately 1,000 Å.

As described above, after the inter-layer insulation layer 32 is recessed, a height difference as deep as the recess depth D occurs between a top surface of the storage node contact spacers 34 and a top surface of the recessed inter-layer insulation layer 32, and thus, the top surface of the inter-layer insulation layer 32 is located at a topologically lower position than the top portion of the storage node contact spacers 34. Therefore, upper corners of the storage node contact spacers 34, adjacent to the recessed inter-layer insulation layer 32, are exposed.

As shown in FIG. 2C, an etch stop insulation layer 36 is formed over the above resulting substrate structure. Herein, the etch stop insulation layer 36 is formed by employing a silicon nitride (Si₃N₄) layer. Portions of the etch stop insulation layer 36 on the upper corners of the storage node contact spacers 34 have a sloped profile, and the etch stop insulation layer 36 gradually becomes thinner as the etch stop insulation layer 36 progresses onto the recessed inter-layer insulation layer 32.

Bottom structures below the etch stop insulation layer 36 have different heights due to the recess process, and thus, a thickness of the silicon nitride layer used as the etch stop insulation layer 36 and the storage node contact spacers 34 is different regionally on the bottom structures.

Hereinafter, to describe the regional difference in thickness of the silicon nitride layer according to the bottom structures, a thickness of the silicon nitride layer on the recessed inter-layer insulation layer 32 is referred to as ‘W1’, a thickness of the silicon nitride layer on the storage node contact plug 35 is referred to as ‘W2’, and a thickness of the silicon nitride layer on the upper portions of the storage node contact spacers 34 (the thickness of the silicon nitride layer from the top surface of the recessed inter-layer insulation layer 32 to a top surface of the etch stop insulation layer 36 including the top portions of the storage node contact spacers 34) is referred to as ‘W3’.

The thicknesses W1 and W2 are identical, and the thickness W3 is thicker than W1 and W2. The reason for W3 being thicker than the rest is because an upper portion of the storage node contact spacers 34 is exposed due to the recessed inter-layer insulation layer 32, and thus, the thickness of the silicon nitride layer is increased as much as the thickness of the upper portion of the storage node contact spacers 34.

Therefore, during a subsequent dry etch process of the etch stop insulation layer 36, the silicon nitride layer is formed the thickest at the upper portion of the storage node contact spacers 34 to minimize an etching amount. Herein, the upper portions of the storage node contact spacers 34 are the most vulnerable regions with respect to storage node contact spacer damage.

As shown in FIG. 2D, an insulation layer 37 for use in a storage node is formed on the etch stop insulation layer 36. Herein, the insulation layer 37 is formed by employing one selected from the group consisting of boro-phospho-silicate glass (BPSG), undoped silicate glass (USG), high density plasma (HDP), and tetraethyle orthosilicate (TEOS).

Subsequently, the insulation layer 37 and the etch stop insulation layer 36 are sequentially dry etched to form an opening 38 exposing a top portion of the storage node contact plug 35.

During the dry etch process for forming the opening 38, especially, while the etch stop insulation layer 36 is etched, an excessive etching occurs, and the surface of the storage node contact plug 35 is completely exposed. Herein, an etch loss may occur to the storage node contact spacers 34 by the storage node contact spacer damage.

However, in this specific embodiment of the present invention, the silicon nitride layer is formed very thickly at the upper portion of the storage node contact spacers 34, which is the most vulnerable region with respect to the storage node contact spacer damage, and thus, the storage node contact spacer damage is minimized.

With respect to the etching amount during the dry etch process for forming the opening 38, although the etching amount of the silicon nitride layer at the upper portions of the storage node contact plug 35 and the inter-layer insulation layer 32 is limited to the thicknesses of W1 and W2 in FIG. 2C, the etching amount of the silicon nitride layer at the adjacent region of the storage node contact plug 25 is very thick including the exposed upper portion of the storage node contact spacers 34 and the etch stop insulation layer 36.

Therefore, because the thickness of the silicon nitride layer is increased as much as the recessed depth on the vulnerable regions with respect to the storage node contact spacer damage, the storage node contact spacers 34 will not be excessively etched to generate a crevasse even if the etch process is performed until the surface of the storage node contact plug 35 is exposed during the etch process of the etch stop insulation layer 36.

By recessing the inter-layer insulation layer 32 in the uniform thickness to form the silicon nitride layer very thickly at the vulnerable regions with respect to the storage node contact spacer damage, the crevasse generated by the excessive etching of the silicon nitride layer used as the storage node contact spacers 34 during the dry etch process of the etch stop insulation layer 36 for forming the opening 38 is prevented, and as a result, a flat structure is achieved.

As shown in FIG. 2E, a barrier metal 39 is formed before a subsequent TiN bottom electrode is formed.

For example, a Ti layer is formed by employing a physical vapor deposition (PVD) method or a chemical vapor deposition (CVD) method on the above resulting substrate structure, and then an annealing process is performed to form a titanium silicide (TiSiₓ) layer. Non-reacted portions of the Ti layer is removed by a wet etch process. Herein, the TiSiₓ layer, which is the barrier metal 39, is formed by a reaction between the Ti layer and silicon in the polysilicon layer used as the storage node contact plug 35. The TiSiₓ layer does not form on the inter-layer insulation layer 32 or the storage node contact spacers 34 adjacent to the storage node contact plug 35.

By forming the TiSiₓ layer, which is the barrier metal 39, resistance on a contacting surface between the storage node contact plug 35 and the subsequent TiN bottom electrode can be decreased.

Subsequently, a storage node isolation process is performed to form the TiN bottom electrode 40 contacting the storage node contact plug 35 in the opening 38.

The storage node isolation process for forming the TiN bottom electrode 40 includes: forming a TiN layer on the insulation layer 37 and the opening 38 by a CVD method, a PVD method, or an atomic layer deposition (ALD) method; and removing portions of the TiN layer on the insulation layer 37, excluding a portion of the TiN layer on the opening 38, by employing a chemical mechanical polishing (CMP) process or an etch-back process to form the TiN bottom electrode 40. Herein, abrasives or etched particles may be attached inside the TiN bottom electrode 40 during the CMP process or the etch-back process. Thus, the opening 38 is completely filled with a photoresist layer with a satisfactory step-coverage characteristic, and then the CMP process or the etch-back process is performed on the TiN layer until the insulation layer 37 is exposed. Then, the photoresist layer is removed by an ashing process.

Furthermore, a dielectric layer 41 and a TiN upper electrode 42 are sequentially formed on the TiN bottom electrode 40 to complete the capacitor.

Herein, the dielectric layer 41 is formed with one selected from the group consisting of oxide-nitride-oxide (ONO), hafnium oxide (HfO₂), aluminum oxide (Al₂O₃), and tantalum oxide (Ta₂O₅). Since the bottom surface in the opening 38 is planarized, a deposition process disregarding step-coverage can be employed. A deposition process disregarding step-coverage can be also employed to the TiN upper electrode 42, that is, a CVD, a PVD, or an ALD method can be used.

Because the crevasse has not been formed adjacent to the storage node contact plug 35 during the formations of such dielectric layer 41 and TiN upper electrode 42, a space for the TiN deposition for use in the TiN upper electrode 42 is not blocked, and the projection is not generated on the dielectric layer 41 and the TiN upper electrode 42.

Although the specific embodiment of the present invention describes the case of using TiN in the bottom electrode, this invention can be applied in formation processes of other types of capacitors using a nitride-based material in the storage node contact spacers.

In accordance with the specific embodiment of the present invention, through the recess process of the inter-layer insulation layer and minimizing the storage node contact spacer damage adjacent to the storage node contact plug by forming the silicon nitride layer thicker on the regions, which are vulnerable to the storage node contact spacer damage during the recessing of the etch stop insulation layer, a leakage current source can be removed, and thus, a capacitor yield can be improved. Accordingly, as the leakage current source is removed, the design rule for the micro-patterning can be secured, and a processing margin can be maximized.

The present application contains subject matter related to the Korean patent application No. KR 2004-0114013, filed in the Korean Patent Office on Dec. 28, 2004, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor memory device, comprising:
forming an inter-layer insulation layer with a storage node contact hole on a substrate;
forming storage node contact spacers on sidewalls of the inter-layer insulation layer in the storage node contact hole;
forming a storage node contact plug in the storage node contact hole;
recessing the inter-layer insulation layer in a predetermined depth;
forming an etch stop insulation layer and an insulation layer over the resulting structure obtained from the recessing of the inter-layer insulation layer;
sequentially dry etching the insulation layer and the etch stop insulation layer to form an opening, exposing a portion of the storage node contact spacers and the storage node contact plug;
forming a bottom electrode in the opening; and
sequentially forming a dielectric layer and an upper electrode on the bottom electrode.

2. The method of claim 1, wherein the inter-layer insulation layer includes an oxide layer.

3. The method of claim 1, wherein the recessing of the inter-layer insulation layer in the predetermined depth is performed by employing a dry etch process to selectively etch the inter-layer insulation layer without etching the storage node contact plug and the storage node contact spacers.

4. The method of claim 1, wherein the recessing of the inter-layer insulation layer in the predetermined depth is performed by employing a wet etch process to selectively etch the inter-layer insulation layer without etching the storage node contact plug and the storage node contact spacers.

5. The method of claim 3, wherein the dry etch process is performed in a radio frequency (RF) plasma chamber.

6. The method of claim 3, wherein the dry etch process employs a fluorine-based gas to maintain an etch rate of the inter-layer insulation layer faster than those of the storage node contact plug and the storage node contact spacers.

7. The method of claim 6, wherein the etch rate of the inter-layer insulation layer is approximately 2 to 4 times faster than those of the storage node contact plug and the storage node contact spacers.

8. The method of claim 6, wherein the fluorine-based gas includes one of hexafluoroethane (C₂F₆) and carbon tetrafluoride (CF₄).

9. The method of claim 4, wherein the wet etch process employs one of a hydrogen fluoride (HF) solution and a buffered oxide etchant (BOE) solution.

10. The method of claim 1, wherein the predetermined recess depth of the inter-layer insulation layer ranges from approximately 500 Å to 1,000 Å.

11. A method for fabricating a semiconductor memory device, comprising:
forming an oxide-based inter-layer insulation layer with a storage node contact hole on a substrate;
forming nitride-based storage node contact spacers on sidewalls of the inter-layer insulation layer in the storage node contact hole;
forming a polysilicon-based storage node contact plug in the storage node contact hole;
recessing the inter-layer insulation layer in a predetermined depth;
forming a nitride-based etch stop insulation layer and an oxide-based insulation layer over the resulting structure obtained from the recessing of the inter-layer insulation layer;
sequentially dry etching the insulation layer and the etch stop insulation layer to form an opening, exposing a portion of the storage node contact plug and the storage node contact spacers;
forming a bottom electrode in the opening; and
sequentially forming a dielectric layer and an upper electrode on the bottom electrode.

12. The method of claim 11, wherein the recessing of the inter-layer insulation layer in the predetermined depth is performed by employing a dry etch process to selectively etch the inter-layer insulation layer without etching the storage node contact plug and the storage node contact spacers.

13. The method of claim 11, wherein the recessing of the inter-layer insulation layer in the predetermined depth is performed by employing a wet etch process to selectively etch the inter-layer insulation layer without etching the storage node contact plug and the storage node contact spacers.

14. The method of claim 12, wherein the dry etch process is performed in an RF plasma chamber.

15. The method of claim 12, wherein the dry etch process employs a fluorine-based gas to maintain an etch rate of the inter-layer insulation layer faster than those of the storage node contact plug and the storage node contact spacers.

16. The method of claim 15, wherein the etch rate of the inter-layer insulation layer is approximately 2 to 4 times faster than those of the storage node contact plug and the storage node contact spacers.

17. The method of claim 15, wherein the fluorine-based gas includes one of C₂F₆ and CF₄.

18. The method of claim 13, wherein the wet etch process employs one of an HF solution and a BOE solution.

19. The method of claim 11, wherein the predetermined recess depth of the inter-layer insulation layer ranges from approximately 500 Å to 1,000 Å.
